(19) United States
(12) Patent Application Publication
(10) Pub. No.: US 2023/0131446 A1
(43) Pub. Date: Apr. 27, 2023

(54) SIMULATION METHOD FOR A PIXEL HEADLAMP SYSTEM

(71) Applicant: dSPACE GmbH, Paderborn (DE)

(72) Inventor: Nico Rueddenklau, Liebenau (DE)

(21) Appl. No.: 17/996,950

(22) PCT Filed: Apr. 21, 2021
(86) PCT No.: PCT/EP2021/060350

§ 371 Date: Oct. 24, 2022

(30) Foreign Application Priority Data
May 6, 2020 (DE) 10 2020 112 284.5

(51) Int. Cl. G06F 30/27

(52) U.S. Cl. CPC G06F 30/27

(57) ABSTRACT

The invention relates to a method for producing control for a real pixel headlamp, which control can be used to control the two-dimensional distribution of the illumination intensity for that area of a scene that is illuminable with the pixel headlamp on the basis of features of different regions of the illuminable area of the scene. This provides a method of this kind that allows automatic capture of a physical selection region that is dependent on a light function and automatic changing of the light intensity of the pixels affected for the physical selection region.

### CROSS-REFERENCE TO PRIOR APPLICATIONS

This application is a U.S. National Phase application under 35 U.S.C. § 371 of International Application No. PCT/EP2021/060350, filed on Apr. 21, 2021, and claims benefit to German Patent Application No. DE 10 2020 112 284.5, filed on May 6, 2020. The International Application was published in German on Nov. 11, 2021 as WO 2021/224004 A1 under PCT Article 21(2).

### FIELD

The invention relates to a simulation method for a pixel headlamp system, and in particular to a method for configuring light functions of an actual pixel headlamp system comprising at least one actual pixel headlamp, the two-dimensional distribution of the illuminance in that area of a scene that can be illuminated by the pixel headlamp being able to be controlled on the basis of features of different regions of the illuminable area of the scene.

### BACKGROUND

In the present disclosure, pixel headlamps should be understood as headlamps for the automotive sector that have a multiplicity of discretely actuable light sources. The overall light distribution of the light sources can be freely configured by all the light sources cooperating over large areas, and can be adapted within just a few milliseconds. In general, LED chips, which have a multiplicity of discretely actuable light dots or “pixels,” are used as the light sources. Since at least two headlamps are normally installed in each car, typical pixel headlamp systems generally have at least two pixel headlamps, which are arranged spatially separately from one another and generate a joint overall light distribution.

The term “illuminable area” means the maximum area that the pixel headlamps can illuminate when all the pixels are at full power. The illuminable area represents a limit for the light functions since a two-dimensional distribution of the illuminance cannot reach beyond the maximum illuminable area. The overall light distribution can thus be adapted, meaning that the two-dimensional distribution of the illuminance happens solely within the illuminable area. The illuminable area may also be restricted by obstructions, such as walls or large trees, since they limit the range of the illuminance.

Pixel headlamps of this kind make it possible to expand the conventional scope of application of motor vehicle headlamps. They provide the technical preconditions for new light functions, such as glare-free high beam, road marking lights, and/or symbol projections. Glare-free high beam allows the high beam to be continually used without the lights having to be dimmed as a whole when there is oncoming traffic. Owing to the discretely actuable light sources, the light intensity can be adapted in specific regions such as the driver side of the passenger compartment of the oncoming vehicle. As a result, in the example application of glare-free high beam, only the driver side of the passenger compartment of the oncoming vehicle is shaded. The illuminable area outside the driver side of the passenger compartment can continue to be illuminated. As a consequence, safety when driving at night is considerably increased and manually dimming and undimming the lights is no longer absolutely necessary.

However, not only can discrete regions be shaded, i.e., the light intensity therein reduced, but also discrete regions can be brightened by increasing the light intensity. As a result, lines and/or symbols, for example, can be projected onto the road such that warning signs and/or road signs recorded at the roadside can appear as projections in the illuminable area and be located in the direct field of vision of the car driver. Moreover, auxiliary lines may be projected onto the road, which, for example, display the vehicle width or act as distance warnings so that the actual width of the vehicle can be better estimated in relation to a narrower lane, or so as to allow for dynamic warning functions.

To be able to implement these light functions in a controlled manner, it is advantageous to have precise control of each discrete light source depending, for example, on the driving situation, the condition of the actual vehicle, and environmental influences. Therefore, the lighting intensity of each discrete pixel should be calculated in a highly dynamic manner and the light distribution should be constantly recalculated at a high clock rate to be able to react directly to changes in the external influences.

To integrate pixel headlamp light functions of this kind into road traffic, a multiplicity of complex pre-calculations are required, along with thorough programming of control software for the pixel headlamps, in order to ensure the system functions reliably. With the function of the glare-free high beam in particular, actual events have to be continually recorded and properly assessed to be able then to reliably control the discrete pixels. Erroneous control of the pixels, particularly in the case of glare-free high beam, causes a high risk of road traffic accidents.

Consequently, calculating the light distribution of all the pixels is a highly complex challenge. Quite often, therefore, actual night drives are performed beforehand so that they can be used later as a basis for calculating the light distribution. However, actual night drives are not only dangerous but also time-consuming and expensive. Yet these drawbacks can be overcome using interactive night driving simulations.

Specifically, the “LucidDrive” simulation environment from the “LucidShape” software package by Synopsys, for example, makes it possible to simulate pixel headlamp systems using the “AFS Masking PixelLight Feature.” It renders the overall light distribution of all the pixels at full power. Discrete regions can then be shaded out of this overall light distribution. In the example application of glare-free high beam, the region of the driver side of the passenger compartment of the oncoming vehicle is shaded. However, the drawback of this simulation environment is that the calculation is carried out irrespective of the nature of the pixel headlamps and thus without taking account of an achievable headlamp-specific implementation.

In addition, the “ALiSiA” software by Hella KGaA provides another possible solution for the simulation-based configuration of light functions for pixel headlamps. To visualize the light distribution of the two headlamps, the light distribution per headlamp is projected onto a measurement surface that is vertically in front of each headlamp. In the process, the light distribution can be influenced by adjustable parameters. A video recording of an actual night drive is superimposed on the projection onto a vertical measurement surface of the overall light distribution. By varying the adjustable parameters, the projected overall light distribution can be adapted until such a point as it appears in the video recording of the actual night drive appropriately according to the desired light function. Superimposing the video recording of an actual night drive on the projection of the overall light distribution leads to uncertainty in terms of the accuracy of the overall light distribution in the surroundings of the video recording. Firstly, this is because the overall light distribution is projected merely onto a vertical measurement surface in front of the headlamps, meaning that the actual lighting effect cannot be displayed. Secondly, environmental influences, for example reflective surfaces or distance-related attenuation, cannot be taken into account for the display of the overall light distribution. The “ALiSiA” software therefore can visually display only an approximation of the actual overall light distribution.

However, these conventional methods do not allow external environmental influences during night driving, for example reflective surfaces or distance-related attenuation, to be taken into account in the calculation of the overall light distribution, nor do they allow the overall light distribution to be visually displayed in a realistic manner.

### SUMMARY

In an exemplary embodiment, the present invention provides a method for configuring light functions of an actual pixel headlamp system comprising an actual pixel headlamp. A two-dimensional distribution of the illuminance in an illuminable area of a scene illuminable by the actual pixel headlamp based on features of different regions of the illuminable area of the scene. The method includes: a) defining a virtual driving scenario, wherein the virtual driving scenario comprises a road and the road surroundings, wherein the road surroundings include vegetation, curbs, road signs, road markings, road users, and/or weather-related features; b) defining a virtual motor vehicle, wherein the virtual motor vehicle has a virtual pixel headlamp corresponding to the actual pixel headlamp and a virtual surroundings sensor for recording at least a portion of an illuminable area illuminable by the virtual pixel headlamp; c) simulating a night drive of the virtual motor vehicle in the defined virtual driving scenario, with the virtual pixel headlamp switched on, by simulating successive virtual scenes, wherein each virtual scene represents a still image from the simulated night drive together with the virtual motor vehicle in the defined virtual driving scenario; d) recording virtual surroundings data by the virtual surroundings sensor in a recordable portion, which is recordable by the virtual surroundings sensor, of the illuminable area illuminable by the virtual pixel headlamp in at least one of the virtual scenes; e) analyzing the recorded virtual surroundings data to automatically identify a spatial selection region in the virtual scene, wherein the spatial selection region indicates a region in which illuminance is to be changed due to a predefined illumination rule dependent on features of different regions of the illuminable area of the scene; f) determining a group of pixels of the virtual pixel headlamp that are affected based on the identified spatial selection region, and changing individual light intensities of discrete affected pixels in the determined group of pixels of the virtual pixel headlamp according to the illumination rule; g) re-recording virtual surroundings data by the virtual surroundings sensor in the recordable portion; h) analyzing the re-recorded virtual surroundings data as to whether an obtained light intensity satisfies the illumination rule in the spatial selection region; and performing one of the following steps based on whether or not the obtained light intensity satisfies the illumination rule: i) generating and storing value pairs for a control to be created based on the obtained light intensity satisfying the illumination rule, wherein the value pairs are formed from the group of pixels and respective change amounts for the discrete pixels in the group; or j) determining a new group of pixels of the virtual pixel headlamp that are affected based on the identified spatial selection region, wherein the new group differs from the previously determined group at least on account of one pixel, and/or further changing the individual light intensities of the discrete pixels of the virtual pixel headlamp according to the illumination rule, wherein a change amount for at least one pixel differs from the change amount for the at least one pixel in the previously determined group, and repeating steps g), h), and i) or j).

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 schematically shows a virtual scene of a simulated driving scenario;

FIG. 2a schematically shows a virtual scene of a simulated driving scenario from the perspective of the vehicle driver, along with a visualized two-dimensional overall light distribution;

FIG. 2b schematically shows a virtual scene of a simulated driving scenario from the perspective of the vehicle driver, along with a different visualized two-dimensional overall light distribution;

FIG. 3a schematically shows a visualized two-dimensional overall light distribution;

FIG. 3b shows an arrangement of pixel arrays;

FIG. 4a schematically shows another visualized two-dimensional overall light distribution; and

FIG. 4b shows the arrangement of pixel arrays from FIG. 3b having different current values per pixel.

### DETAILED DESCRIPTION

Exemplary embodiments of the invention provide a method for configuring light functions of an actual pixel headlamp system which allows for the automated control of the two-dimensional distribution of the illuminance of the area that can be illuminated by a pixel headlamp of the pixel headlamp system on the basis of features of different regions of the illuminable area, particularly on the basis of dynamic oncoming traffic, and which makes it possible, for that purpose, to design the simulation of freely selectable driving scenarios in a realistic manner such that the overall light distribution of the pixel headlamp system can be calculated while taking account of vehicle-specific and/or environment-specific influences.

Therefore, according to the invention, a method for configuring light functions of an actual pixel headlamp system comprising at least one actual pixel headlamp is provided, comprising the following method steps:

a) defining a virtual driving scenario, the virtual driving scenario comprising a road and the road surroundings, in particular vegetation, curbs, road signs, road markings, road users, and/or weather-related features,
b) defining a virtual motor vehicle, the virtual motor vehicle having a virtual pixel headlamp corresponding to the actual pixel headlamp, and a virtual surroundings sensor for recording at least a portion of the area that can be illuminated by the virtual pixel headlamp,
c) simulating a night drive of the virtual motor vehicle in the defined virtual driving scenario, with the virtual pixel headlamp switched on, by simulating successive virtual scenes, each virtual scene representing a still image from the simulated virtual drive together with the virtual motor vehicle in the defined virtual driving scenario,
d) recording virtual surroundings data by the virtual surroundings sensor in the portion, which can be recorded by the virtual surroundings sensor, of the area that can be illuminated by the virtual pixel headlamp in at least one of the virtual scenes,
e) analyzing the recorded virtual surroundings data to automatically identify at least one spatial selection region in the virtual scene, the spatial selection region indicating the region in which the illuminance needs to be changed owing to a predefined illumination rule that is dependent on features of different regions of the illuminable area of the scene,
f) determining a group of pixels of the virtual pixel headlamp that are affected on the basis of the identified spatial selection region, and changing the individual light intensity of the discrete pixels in the determined group of pixels of the virtual pixel headlamp by a relevant change amount either toward a higher light intensity if the illumination rule prescribes a higher illuminance in the spatial selection region or toward a lower light intensity if the illumination rule prescribes a lower illuminance in the spatial selection region,
g) re-recording virtual surroundings data by the virtual surroundings sensor in the portion, which can be recorded by the virtual surroundings sensor, of the area that can be illuminated by the virtual pixel headlamp in the virtual scene,
h) analyzing the re-recorded virtual surroundings data as to whether the obtained light intensity satisfies the illumination rule in the spatial selection region in the virtual scene,
i) generating and storing value pairs for the control to be created if the obtained illumination satisfies the illumination rule, the value pairs being formed from the group of pixels and the respective change amounts of the discrete pixels in the group, or
j) determining a new group of pixels of the virtual pixel headlamp that are affected on the basis of the identified spatial selection region, which group differs from the previously determined group at least on account of one pixel, and/or changing the individual light intensity of the discrete pixels of the virtual pixel headlamp by a relevant change amount either toward a higher light intensity if the illumination rule prescribes a higher illuminance in the spatial selection region or toward a lower light intensity if the illumination rule prescribes a lower illuminance in the spatial selection region, at least one change amount of one pixel differing from the change amount for the pixel in the previously determined group, and repeating steps g), h), and i) or j).

Where it is stated in the present disclosure that a spatial selection region is automatically identified, this means that the region in which the light intensity of the overall light distribution is intended to be either increased or decreased according to the light function is automatically identified in the virtual scene. This automatic identification does not involve any intervention from a human operator or developer. It is based solely on data that can be derived from the simulation of a virtual night drive. This includes in particular data from the virtual surroundings camera, which scans the surroundings of the driving scenario and can thus deliver data on the surroundings. By way of example, these data may include the oncoming traffic, the light from the headlamps of the oncoming traffic, and vegetation at the roadside or the road conditions and road signs located in the recording range of the surroundings camera. In particular, a wet road surface and the road signs may make a significant contribution to the overall light distribution since they generally have reflective surfaces. The spatial selection region can thus be identified while taking account not only of the oncoming traffic but also of the surroundings and the influence thereof on the overall light distribution of the pixel headlamp system.

When the spatial selection region is recorded, a group of affected pixels is determined; this group can bring about a change in the light distribution in the spatial selection region by changing the light intensity of the affected pixels. The light intensity is adjusted by a relevant change amount, by either increasing or decreasing the light intensity of the affected pixels, such as to create a higher or lower light intensity.

Once the light intensities of the affected pixels have been changed, the virtual surroundings data are re-recorded and analyzed as to whether the obtained light function satisfies the illumination rule in the spatial selection region in the virtual scene. If this is the case, value pairs for the control to be created are formed from the group of pixels and the respective change amounts of the discrete pixels in the group. If the obtained light function does not satisfy the illumination rule, a new group of affected pixels is determined, which differs from the previously determined group at least on account of one pixel. The light intensity of the new group of the affected pixels is then changed, and the check as to whether the light function satisfies the illumination rule is carried out again.

The invention thus allows a spatial selection region to be automatically recorded according to a plurality of different selectable light functions, and allows the light intensities of discrete affected pixels to be automatically adapted in order to implement the light function. The basis for identifying the spatial selection region and adapting the light intensities is the virtual driving scenario. Since this driving scenario is defined and simulated in advance, the light function can be visually displayed for a multiplicity of different driving scenarios.

In an embodiment, the value pairs from the group of pixels and the respective change amounts are supplied as training data. By way of example, a neural network can be trained thereby. The neural network is thus utilized in a time- and cost-effective manner.

In addition, according to an embodiment, an actual pixel headlamp is controlled by storing value pairs from the group of pixels and the respective change amounts of the discrete pixels in the group, integrating the stored value pairs on a control device, and retrieving the stored value pairs. This also allows the value pairs to be stored without exceeding the storage capacity of the graphics chip on the graphics chip of the control device and thus makes it possible to ensure that the multiplicity of pixels are controlled in a highly dynamic manner.

According to an embodiment, the spatial orientation in the virtual scene is done on the basis of a global three-dimensional coordinate system. The global coordinates are transferred into a headlamp-specific coordinate system. This ensures that the basic calculation is carried out independently of the headlamp and that the global coordinates are not transferred into the coordinate system of the headlamp until a later step. The simulation is thus performed irrespective of the nature of the pixel headlamp system, so a multiplicity of different pixel headlamp systems can be implemented by the subsequent conversion.

The invention makes it possible not only to record and analyze the surroundings data but also to record and analyze the vehicle data. In this respect, according to an embodiment, the virtual motor vehicle has at least one virtual environment camera and/or at least one virtual brightness sensor as a surroundings sensor and/or at least one virtual vehicle sensor for recording vehicle data, in particular the acceleration and/or the steering angle and/or the yaw rate. Using an additional brightness sensor, the light distribution of the surroundings, which is influenced for example by light reflections or shadows, can be recorded and taken into account to determine the group of affected pixels for changing the light intensities. By way of example, the light intensity of an affected pixel has to be increased to a lesser extent for a selected light function if any light reflections mean that the light intensity is higher in the desired region than the light intensity that merely emanates from the pixel headlamp system.

Preferably, the method has the following additional method steps:
recording virtual vehicle data by the at least one virtual vehicle sensor of the virtual motor vehicle,
analyzing the recorded vehicle data to determine a second group of pixels of the virtual pixel headlamp on the basis of the recorded vehicle data, and
changing the individual light intensity of the discrete pixels in the second determined group of pixels of the virtual pixel headlamp by a relevant change amount either toward a higher light intensity if the illumination rule prescribes a higher illuminance in the spatial selection region when the recorded vehicle data are taken into account or toward a lower light intensity if the illumination rule prescribes a lower illuminance in the spatial selection region when the recorded vehicle data are taken into account.

In general, this means that a second group of pixels that are affected for a light function is determined and the recorded vehicle data are also taken into account for this purpose. The steering behavior and the speed of the vehicle may affect the light function. For example, in the case of the glare-free high beam light function, the region to be illuminated can be made bigger or smaller depending on the vehicle speed. Moreover, the projection of auxiliary lines and/or symbols may be relative to driving around corners, such that the auxiliary lines and/or symbols can be projected into the course of a corner.

In addition, the second group of pixels is preferably a subset of the first group of pixels. This ensures that a pixel may be affected on the basis of both environment data and vehicle data for a particular light distribution, and the adaptation of the light intensity of the affected pixel from the subset is not assigned two different change amounts but rather the change amount takes account of both influences equally.

Furthermore, in an embodiment, the presentation of the virtual scenes one after the other is clocked such that the number of virtual scenes per second is predetermined and the number of repetitions of step j) either corresponds to the number of repetitions required until the obtained illumination satisfies the illumination rule or corresponds to the number of repetitions that is temporally possible under the clock rate before the next lined-up virtual scene is analyzed, depending on which condition applies earliest. This ensures that the repetition of step j) is finite. In the event that no light distribution that satisfies the illumination rule is achieved for a virtual scene, step j) is not repeated indefinitely but only until such a point as the next lined-up virtual is analyzed.

Where it is stated in the present disclosure that a light distribution satisfies an illumination rule, this means that the overall light distribution of the pixel headlamp system of the desired overall light distribution complies with the illumination rule within a certain margin of error or within a certain permissible deviation. It thus does not mean that the overall light distributions have to be exactly the same. Rather, it means that the overall light distribution of the illumination rule has tolerance limits. The overall light distribution of the pixel headlamp system has to be integrated within the tolerance limits of the illumination rule so that the overall light distribution of the pixel headlamp system “satisfies” the overall light distribution of the illumination rule.

According to an embodiment, the illumination rule is determined by a desired two-dimensional distribution of the illuminance, which is dependent on the desired light function, in particular glare-free high beam and/or the projection of lines and/or symbols onto the road. As a result, the different light functions determine the respective different desired two-dimensional distributions of the illuminance of the pixels (also referred to as the overall light distribution). Glare-free high beam has a different desired overall light distribution from the projection of auxiliary lines onto the road. Depending on the light function, discrete regions of the overall light distribution have to be either brightened or darkened, i.e., the light intensity of discrete pixels has to be increased or decreased.

In principle, the change in the individual light intensity of discrete pixels is made possible in many different ways. According to an embodiment, however, the individual light intensities are changed by a relevant change amount by way of a dimming factor d, where d<1 if the light intensity is intended to be decreased and d>1 if the light intensity is intended to be increased, and the dimming factor is multiplied by the individual light intensity of each pixel. Using the dimming factor, a new set of dimming values is calculated for the light intensities of the affected pixels.

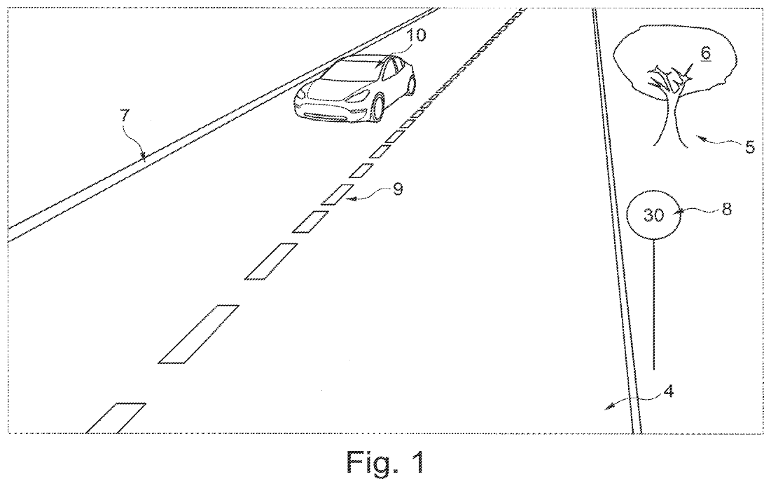

FIG. 1 schematically shows an example virtual driving scenario 3. To simulate this driving scenario, a road 4, the road surroundings 5, the vegetation 6 at the roadside, the curbs 7, a road sign 8, the road markings 9, and other road users 10 were defined. However, defining the virtual driving scenario determines not only the position of each feature but also the nature thereof, for example the reflectivity of a road sign. Each defined feature can affect the later calculation of the light distribution since they, for example, may absorb or reflect light and this behavior influences the overall light distribution. Therefore, it is advantageous to define any virtual driving scenario thoroughly at the beginning.

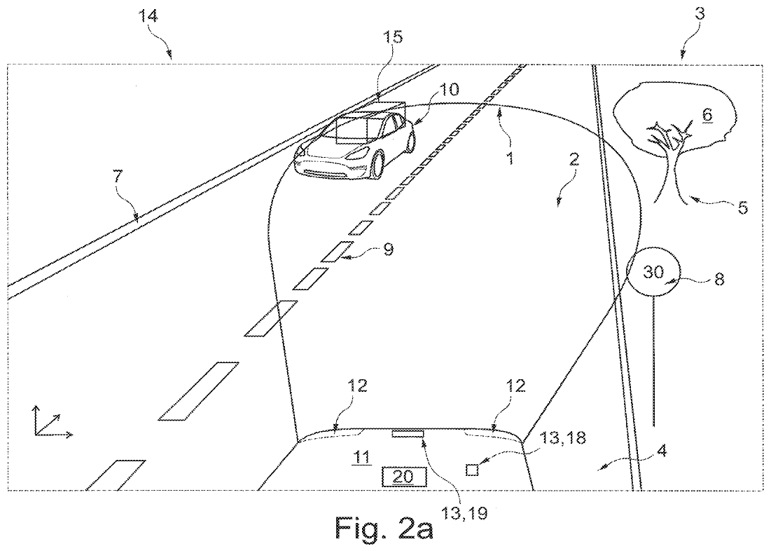

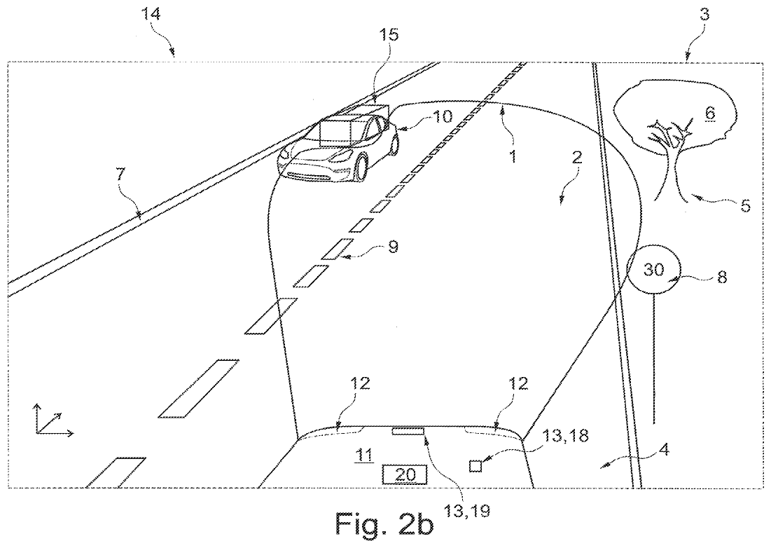

FIG. 2a schematically shows a virtual scene 14 of the previously defined virtual driving scenario 3 from the perspective of the driver of the virtual motor vehicle 11. The virtual motor vehicle 11 is driving in the right-hand lane of the road 4, which is demarcated by road markings 9. Another road user 10 is coming toward the virtual motor vehicle 11 on the opposite side of the road, and is therefore the oncoming traffic. The virtual motor vehicle 11 is equipped with two virtual pixel headlamps 12 and with virtual surroundings sensors 13, which are implemented in the form of a virtual environment camera 18 and a virtual brightness sensor 19. In addition, the motor vehicle 11 has a virtual vehicle sensor 20.

In FIG. 2a, the sensors are positioned on the hood. This is not generally the case in reality. The sensors 18, 19, 20 may instead be installed on the windshield or at other locations on the motor vehicle 11, depending on their function. However, the position of the sensors 18, 19, 20 is immaterial for the invention. For this reason, they are shown on the hood for the sake of simplicity. In FIG. 2, the virtual pixel headlamps 12 are switched on and the high beam is activated so that a two-dimensional distribution of the illuminance 1 is visible, which demarcates an illuminable area 2. It can be seen that if the light intensities of the discrete pixels 21 were not changed, the two-dimensional distribution of the illuminance 1 would include the vehicle driver of the oncoming road user 10 and thus dazzle the vehicle driver. Therefore, a spatial selection region 15 is automatically determined. In this spatial selection region 15, the light intensity of the affected pixels 17 is to be adapted so that the two-dimensional distribution of the illuminance 1 no longer covers the spatial selection region 15 and the driver of the oncoming vehicle is no longer dazzled.

This situation is shown schematically in FIG. 2b. The light intensities of the affected pixels 17, and thus the two-dimensional distribution of the illuminance 1, have been changed. It can be seen that the spatial selection region 15 is no longer covered by the two-dimensional distribution of the illuminance 1. The oncoming road user 10 is thus not dazzled. The rest of the illuminable area 2, however, remains fully illuminated since only the light intensity of the pixels 17 affected for the spatial selection region 15 has been changed.

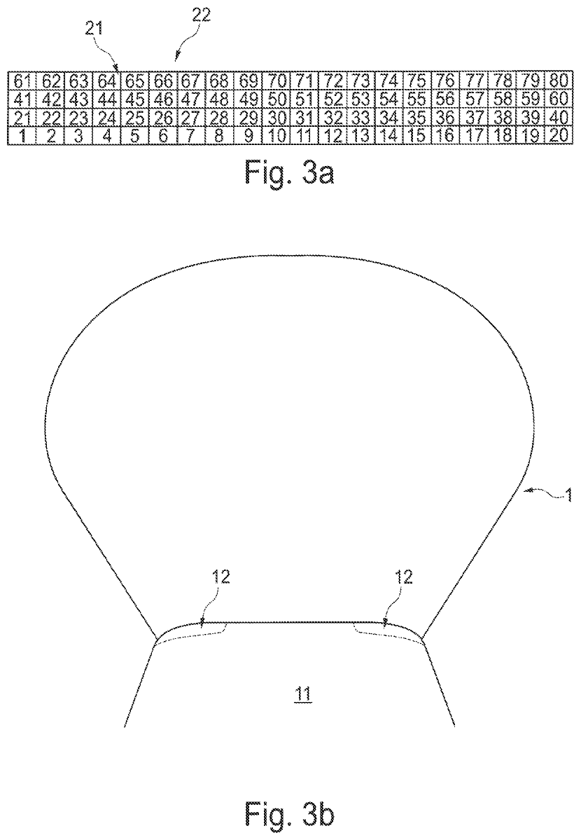

FIGS. 3a-3b schematically show the relationship between the pixels 21 in a pixel array 22 (FIG. 3a) and the two-dimensional distribution of the illuminance 1 (FIG. 3b) for the virtual scene 14 of the virtual driving scenario 3 from FIG. 2a. The pixel headlamps are switched on and all the pixels 21 of the pixel array 22 are at full power. Account is not taken of any influences from the environment or from the vehicle condition. The two-dimensional distribution of the illuminance 1 resembles the light distribution of a conventional headlamp without a multiplicity of pixels 21 as a light source.

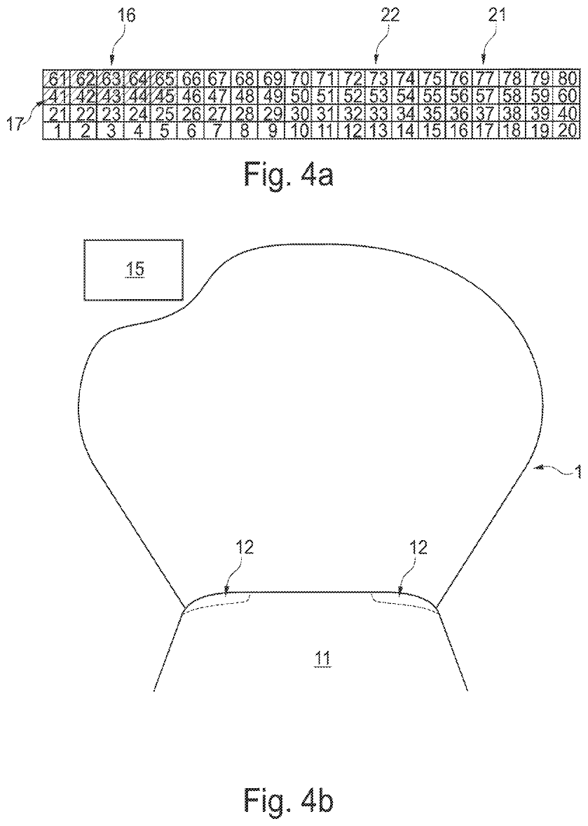

FIGS. 4a-4b show the relationship between the pixels 21 in a pixel array 22 (FIG. 4a) and the two-dimensional distribution of the illuminance 1 (FIG. 4b) for the virtual scene 14 of the virtual driving scenario 3 from FIG. 2b. Using the virtual surroundings sensors 13, 18, 19 and the virtual vehicle sensor 20, a spatial selection region 15 was able to be automatically determined.

The group 16 of affected pixels 17, out of all the pixels 21 of the pixel array 22, that is relevant for the spatial selection region 15 is then determined. The light intensity of the affected pixels 17 is changed according to the light function. The light function in this example application is glare-free high beam.

The aim of the light function is therefore to adapt the two-dimensional distribution of the illuminance 1 to such an extent as to not dazzle the driver of the oncoming traffic, who is encompassed by the spatial selection region 15, by decreasing the light intensity in the spatial selection region 15. It can be seen in FIG. 4a that the pixels numbered 41 to 45 and 61 to 65 belong to the group 16 of affected pixels 17. The light intensity of these pixels 17 is decreased by adapting the current values of each discrete pixel 17 in the affected group 16. The resulting two-dimensional distribution of the illuminance is shown schematically in FIG. 4b. It can be seen that the spatial selection region 15 is no longer covered by the two-dimensional distribution of the illuminance 1. Since the spatial selection region 15 precisely depicts the region in which the oncoming road user 10 is located, as shown in FIGS. 2a and 2b, it can be ensured that the high beam of the pixel headlamp system does not dazzle the driver of the oncoming vehicle, without dimming the headlamp as a whole.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

1 Two-dimensional distribution of the illuminance
2 Illuminable area
3 Virtual driving scenario
4 Road
5 Road surroundings
6 Vegetation
7 Curb
8 Road sign
9 Road marking
10 Road user
11 Virtual motor vehicle
12 Virtual pixel headlamp
13 Virtual surroundings sensor
14 Virtual scene
15 Spatial selection region
16 Group of affected pixels
17 Affected pixels
18 Virtual environment camera
19 Virtual brightness sensor
20 Virtual vehicle sensor
21 Pixel
22 Pixel array

1. A method for configuring light functions of an actual pixel headlamp system comprising an actual pixel headlamp, wherein a two-dimensional distribution of the illuminance in an illuminable area of a scene illuminable by the actual pixel headlamp based on features of different regions of the illuminable area of the scene, comprising:
a) defining a virtual driving scenario, wherein the virtual driving scenario comprises a road and the road surroundings, wherein the road surroundings include vegetation, curbs, road signs, road markings, road users, and/or weather-related features;
b) defining a virtual motor vehicle, wherein the virtual motor vehicle has a virtual pixel headlamp corresponding to the actual pixel headlamp and a virtual surroundings sensor for recording at least a portion of an illuminable area illuminable by the virtual pixel headlamp;
c) simulating a night drive of the virtual motor vehicle in the defined virtual driving scenario, with the virtual pixel headlamp switched on, by simulating successive virtual scenes, wherein each virtual scene represents a still image from the simulated night drive together with the virtual motor vehicle in the defined virtual driving scenario;
d) recording virtual surroundings data by the virtual surroundings sensor in a recordable portion, which is recordable by the virtual surroundings sensor, of the illuminable area illuminable by the virtual pixel headlamp in at least one of the virtual scenes;
e) analyzing the recorded virtual surroundings data to automatically identify a spatial selection region in the virtual scene, wherein the spatial selection region indicates a region in which illuminance is to be changed due to a predefined illumination rule dependent on features of different regions of the illuminable area of the scene;
f) determining a group of pixels of the virtual pixel headlamp that are affected based on the identified spatial selection region, and changing individual light intensities of discrete affected pixels in the determined group of pixels of the virtual pixel headlamp according to the illumination rule;
g) re-recording virtual surroundings data by the virtual surroundings sensor in the recordable portion;
h) analyzing the re-recorded virtual surroundings data as to whether an obtained light intensity satisfies the illumination rule in the spatial selection region; and
performing one of the following steps based on whether or not the obtained light intensity satisfies the illumination rule:
i) generating and storing value pairs for a control to be created based on the obtained light intensity satisfying the illumination rule, wherein the value pairs are formed from the group of pixels and respective change amounts for the discrete pixels in the group; or
j) determining a new group of pixels of the virtual pixel headlamp that are affected based on the identified spatial selection region, wherein the new group group differs from the previously determined group at least on account of one pixel, and/or further changing the individual light intensities of the discrete pixels of the virtual pixel headlamp according to the illumination rule, wherein a change amount for at least one pixel differs from the change amount for the at least one pixel in the previously determined group, and repeating steps g), h), and i) or j).

2. The method according to claim 1, wherein the value pairs from the group of pixels and the respective change amounts are supplied as training data for a neural network.

3. The method according to claim 1, wherein the spatial orientation in the virtual scene is done on the basis of a global three-dimensional coordinate system, and the global coordinates are transferred into a headlamp-specific coordinate system.

4. The method according to claim 1, wherein the virtual motor vehicle has at least one virtual environment camera and/or at least one virtual brightness sensor as at least one surroundings sensor and/or at least one virtual vehicle sensor for recording vehicle data, in particular acceleration and/or steering angle and/or yaw rate.

5. The method according to claim 1, further comprising:
recording virtual vehicle data by the at least one virtual vehicle sensor of the virtual motor vehicle;
analyzing the recorded vehicle data to determine a second group of pixels of the virtual pixel headlamp on the basis of the recorded vehicle data; and
changing individual light intensities of discrete pixels in the second determined group of pixels of the virtual pixel headlamp according to the illumination rule.

6. The method according to claim 5, wherein the second group of pixels is a subset of the first group of pixels.

7. The method according to claim 1, wherein the presentation of the virtual scenes one after the other is clocked such that the number of virtual scenes per second is predetermined and the number of repetitions of step j) either corresponds to the number of repetitions required until the obtained illumination satisfies the illumination rule or corresponds to the number of repetitions that is temporally possible under the clock rate before the next lined-up virtual scene is analyzed, depending on which condition applies earliest.

8. The method according to claim 1, wherein the individual light intensities are changed by respective change amounts based on multiplying each respective individual light intensity by a respective dimming factor.

9. The method according to claim 1, wherein the actual pixel headlamp is controlled by storing value pairs from the group of pixels and respective change amounts of the discrete pixels in the group, integrating the stored value pairs on a control device, and retrieving the stored value pairs.

10. The method according to claim 1, wherein the illumination rule is determined by a desired two-dimensional distribution of the illuminance, which is dependent on a desired light function, in particular glare-free high beam and/or projection of lines and/or symbols onto the road.
